(19) United States
(12) Patent Application Publication
(10) Pub. No.: US 2026/0156878 A1
(43) Pub. Date: Jun. 4, 2026

(54) SEMICONDUCTOR DEVICE AND METHOD OF FORMING THE SAME

(71) Applicant: HON HAI PRECISION INDUSTRY CO., LTD., New Taipei City (TW)

(72) Inventors: Jheng-Sheng YOU, Hsinchu City (TW); Jhe-Hao CHANG, Hsinchu City (TW); Wen-Yuan HSIEH, Hsinchu City (TW)

(21) Appl. No.: 19/052,314

(22) Filed: Feb. 13, 2025

(30) Foreign Application Priority Data
Nov. 29, 2024 (TW) 113146437

(51) Int. Cl. H10D 62/10; H01L 23/00; H01L 23/482; H10D 30/01; H10D 30/47; H10D 64/00; H10D 64/27; H10D 64/60

(52) U.S. Cl. CPC H10D 62/102; H10D 30/015; H10D 64/112; H10D 64/411; H10D 64/60; H10W 20/484; H10D 30/475; H10W 72/019; H10W 72/01951; H10W 72/952

(57) ABSTRACT

A semiconductor device includes a semiconductor substrate having an active region and an isolation region, a gate structure on the active region, and a drain electrode and a source electrode disposed at opposite sides of the gate structure. The semiconductor device includes a dielectric layer, a gate pad, gate plugs, and a first field plate. The dielectric layer covers the semiconductor substrate. The gate pad is disposed on the dielectric layer and overlaps the gate structure in a vertical projection. The gate plugs are disposed in the dielectric layer and on the active region to electrically interconnect the gate pad and the gate structure. The first field plate is disposed on the dielectric layer in the same layer as the gate pad and is spaced apart from the gate pad. The material of the gate pad is the same as the material of the first field plate.

### CROSS-REFERENCE TO RELATED APPLICATION

This application claims priority to Taiwan Application Serial Number 113146437, filed Nov. 29, 2024, which is herein incorporated by reference in its entirety.

### BACKGROUND

### Field of Invention

The present disclosure relates to a semiconductor device and a method of forming the same.

### Description of Related Art

Power semiconductor devices have been rapidly developed and are widely utilized in various fields such as wireless communications, electronic devices, electric vehicles, etc. However, the high power devices require high breakdown voltage, high electron mobility, great thermal stability, etc. Therefore, there is a need to provide an enhanced semiconductor device and method of forming the same.

### SUMMARY

An aspect of the disclosure provides a semiconductor device including a semiconductor substrate including an active region and an isolation region disposed at a side of the active region; a gate structure disposed on the active region of the semiconductor substrate; a source electrode and a drain electrode disposed on the active region of the semiconductor substrate and at opposite sides of the gate structure; a dielectric layer covering the semiconductor substrate, the gate structure, the source electrode, and the drain electrode; and a gate pad disposed on the dielectric layer, wherein the gate pad overlaps the gate structure in a vertical projection. The semiconductor device includes a plurality of gate plugs disposed in the dielectric layer and on the active region of the semiconductor substrate, wherein the plurality of gate plugs electrically connect the gate pad to the gate structure. The semiconductor device includes a first field plate disposed on the dielectric layer, wherein the first field plate is at the same level as the gate pad and is laterally spaced from the gate pad, wherein a material of the gate pad and a material of the first field plate are the same.

Another aspect of the disclosure provides a method of forming a semiconductor device. The method includes defining an active region and an isolation region at a side of the active region in a semiconductor substrate; forming a gate structure on the active region of the semiconductor substrate; forming a drain electrode and a source electrode on the active region of the semiconductor substrate and at opposite sides of the gate structure; forming a dielectric layer covering the semiconductor substrate, the gate structure, the drain electrode, and the source electrode; forming a plurality of gate plugs in the dielectric layer, wherein the plurality of gate plugs are connected to the gate structure; depositing a metal layer on the dielectric layer; and patterning the metal layer to form a gate pad and a first field plate that are laterally separated from each other, wherein the gate pad is connected to the plurality of gate plugs at the active region.

According to some embodiments of the semiconductor device of the disclosure, the first field plate and the gate pad are defined by the same patterning process thus the mask number and the manufacturing processes can be reduced. The height level of the first field plate is different from the height level of the second field plate such that the electric field of the semiconductor device can be tuned. Additionally, the gate structure and the gate pad are connected by the gate plugs at the active region, the gate resistance can be greatly reduced so that the on-off loss can be reduced and the on-off frequency can be improved when component is switched on or off by the gate.

It is to be understood that both the foregoing general description and the following detailed description are by examples, and are intended to provide further explanation of the disclosure as claimed.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is an oblique view of a semiconductor device according to some embodiments of the disclosure.

FIG. 2 to FIG. 5 are cross-sectional views of different stages of a method of forming the semiconductor device according to some embodiments of the disclosure.

FIG. 6 is a cross-sectional view of the semiconductor device according to some other embodiments of the disclosure.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

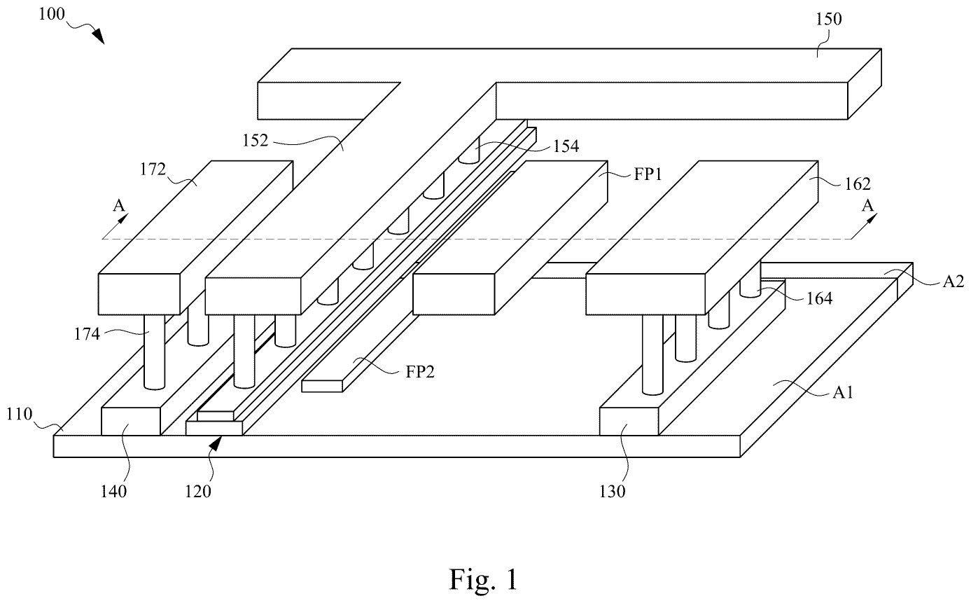

Reference is made to FIG. 1, which is an oblique view of a semiconductor device according to some embodiments of the disclosure. The semiconductor device 100 includes a semiconductor substrate 110. An active region A1 and isolation regions A2 are defined in the semiconductor substrate 110, in which the isolation regions A2 are disposed at opposite sides of the active region A1 (only one side is illustrated in the drawing). The channel layer of the active region A1 is not damaged, and the channel layer of the isolation region A2 is damaged by such as an ion bombard process. The semiconductor device 100 includes a gate structure 120, a drain electrode 130, and a source electrode 140 disposed on the active region A1 of the semiconductor substrate 110. The gate structure 120, the drain electrode 130, and the source electrode 140 are substantially parallel arranged. The drain electrode 130 and the source electrode 140 are disposed at opposite sides of the gate structure 120.

The semiconductor device 100 includes a gate bus 150 disposed on the isolation region A2. The semiconductor device 100 includes a gate pad 152 connected to the gate bus 150 and extended into the active region A1. The extension direction of the gate bus 150 is perpendicular to the extension direction of the gate pad 152. The gate pad 152 overlaps the gate structure 120 in a vertical projection. The semiconductor device 100 further includes a plurality of gate plugs 154. The gate plugs 154 are disposed on the active region A1 and electrically connect the gate pad 152 to the gate structure 120.

The semiconductor device 100 further includes a drain bus (not shown) and a source bus (not shown) disposed at the isolation region (not shown) at another side of the active region A1. The semiconductor device 100 further includes a drain pad 162 connected to the drain bus and extended into the active region A1 and a source pad 172 connected to the source bus and extended into the active region A1. The extension direction of the drain pad 162 and source pad 172 is parallel to the extension direction of the gate pad 152. The semiconductor device 100 further includes a plurality of drain plugs 164 and a plurality of source plugs 174. The drain plugs 164 and the source plugs 174 are disposed on the active region A1. The drain plugs 164 electrically connect the drain pad 162 to the drain electrode 130, and the source plugs 174 electrically connect the source pad 172 to the source electrode 140.

The semiconductor device 100 includes a first field plate FP1 disposed on the active region A1 and disposed between the gate pad 152 and the drain pad 162. The first field plate FP1 is at the same level as the gate pad 152 and the drain pad 162, and the first field plate FP1 is not physically connected to either one of the gate pad 152, the drain pad 162, or the source pad 172, at the level.

The semiconductor device 100 includes a second field plate FP2 disposed on the active region A1. The second field plate FP2 is disposed between the gate structure 120 and the drain electrode 130. The height level of the second field plate FP2 is between the gate structure 120 and the first field plate FP1. In some other embodiments, the first field plate FP1 and the second field plate FP2 can be disposed at the same level and are not physically connected to each other. In some other embodiments, for satisfying different voltage requirements, the second field plate FP2 can be omitted or can include multiple field plates, to better control electric field.

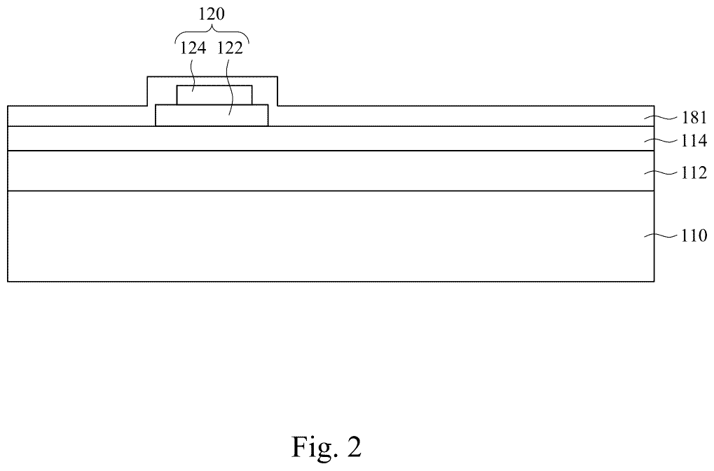

Reference is made to FIG. 2 to FIG. 5, which are cross-sectional views of different stages of a method of forming the semiconductor device according to some embodiments of the disclosure, in which the cross-section can refer to line A-A of FIG. 1. As shown in FIG. 2, the method of forming the semiconductor device includes forming a channel layer 112 on a semiconductor substrate 110, and forming a barrier layer 114 on the channel layer 112. The semiconductor substrate 110 can be a Si substrate or a SiC substrate and can further include semiconductor elements, compound, and/or alloy.

The channel layer 112 can provide a channel between source and drain. The barrier layer 114 is benefit to form a two-dimensional electron gas (2DEG) carrier path within the channel layer 112, in which the 2DEG carrier path has high concentration, high electron mobility, and lower resistance. In some embodiments, the material of the channel layer 112 includes epitaxial GaN. In some embodiments, the material of the barrier layer 114 includes AlGaN.

A gate structure 120 is formed on the barrier layer 114 to control the carrier passing or not of the channel layer 112. In some embodiments, the gate structure 120 includes a patterned doping layer 122 and a gate metal layer 124 on the doping layer 122. The doping layer 122 can be GaN doped with P-type dopants. The material of the gate metal layer 124 can include suitable metal materials, such as TiN.

A first dielectric layer 181 is conformally and continuously formed on the barrier layer 114 and the gate structure 120. The first dielectric layer 181 is directly in contact with the barrier layer 114 and the gate structure 120. In some embodiments, the first dielectric layer 181 covers the barrier layer 114 and continuously covers the top surface and side surfaces of the gate structure 120.

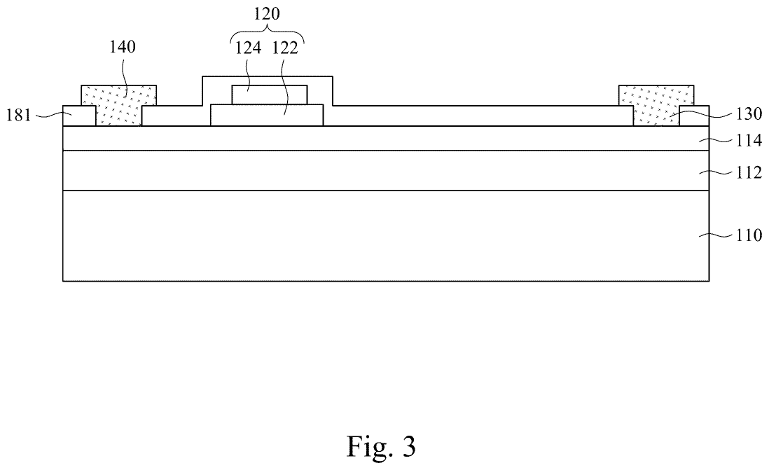

Then, as shown in FIG. 3, a drain electrode 130 and a source electrode 140 are formed at opposite sides of the gate structure 120. The material of the drain electrode 130 and the source electrode 140 is ohmic contact metal which can be selected corresponding to the barrier layer 114. In some embodiments, the ohmic contact metal of the drain electrode 130 and the source electrode 140 includes Ti, Al, AlCu, AlN, Ni, Pt, Au, etc. The drain electrode 130 and the source electrode 140 penetrate the first dielectric layer 181 and contact the barrier layer 114.

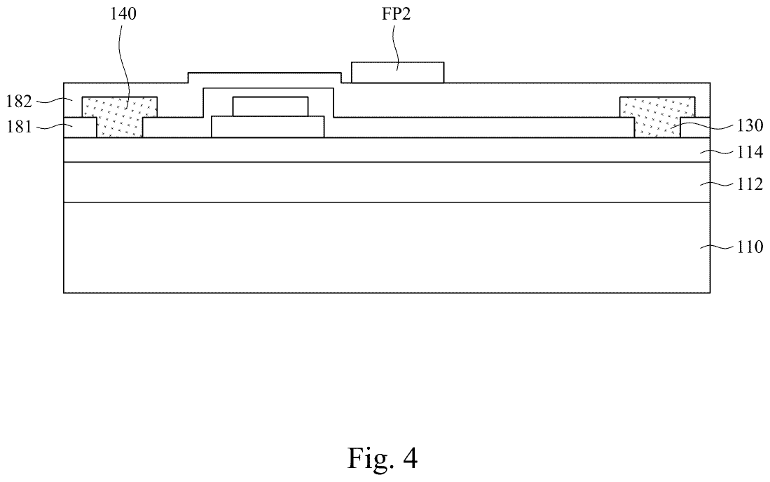

Then, as shown in FIG. 4, a second dielectric layer 182 is formed covering the drain electrode 130, the source electrode 140, and the first dielectric layer 181. In some embodiments, the material of the first dielectric layer 181 and the second dielectric layer 182 includes SiO₂, Si₃N₄, SiON, or combinations thereof. After the second dielectric layer 182 is formed, a patterned photoresist can be formed on a portion of the semiconductor substrate 110 as the active region A1 (see FIG. 1), and portions of the semiconductor substrate 110 as the isolation regions A2 (see FIG. 1) are exposed. A plasma bombard process is then performed to destroy the channel layer 112 in the isolation regions A2. Then the patterned photoresist is removed to define the active region A1 and the isolation regions A2.

A second field plate FP2 is formed on the second dielectric layer 182. The steps of forming the second field plate FP2 include depositing a conductive layer on the second dielectric layer 182 and patterning the conductive layer. In some embodiments, the material of the second field plate FP2 can be TiN. In some other embodiments, for satisfying different voltage requirements, the second field plate FP2 can be omitted or can include multiple field plates, to better control electric field.

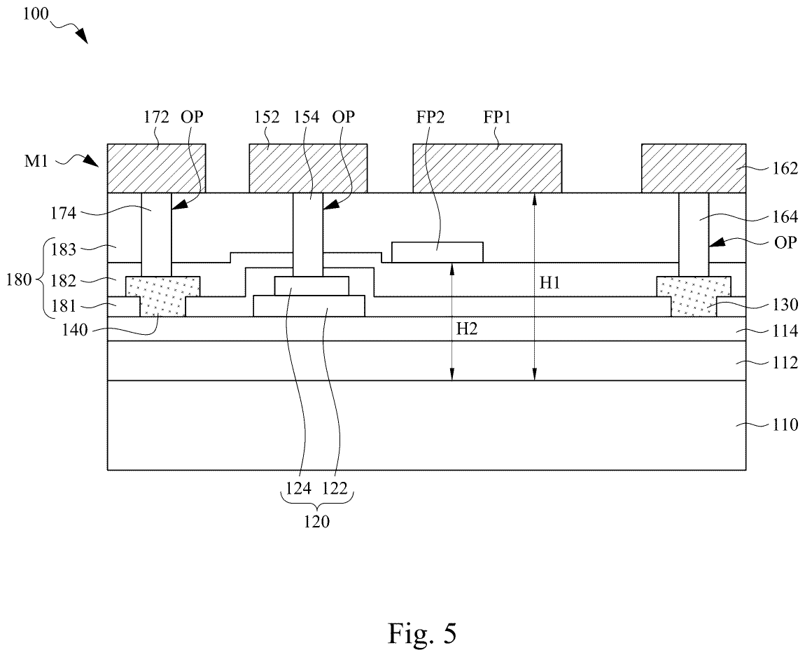

Then, as shown in FIG. 5, a third dielectric layer 183 is deposited on the second dielectric layer 182, and a planarization process is performed such that the third dielectric layer 183 is able to provide a planar top surface. The first dielectric layer 181, the second dielectric layer 182, and the third dielectric layer 183 together can be referred as a dielectric layer 180. The dielectric layer 180 is etched to define a plurality of openings OP therein. A metal material such as tungsten is deposited to fill the openings OP thereby forming a plurality of gate plugs 154 that are connected to the gate structure 120, a plurality of drain plugs 164 that are connected to the drain electrode 130, and a plurality of source plugs 174 that are connected to the source electrode 140.

After the gate plugs 154, the drain plugs 164, and the source plugs 174 are formed on the active region A1, a first metal layer M1 is deposited on the dielectric layer 180 and is patterned to obtain a gate bus 150 (see FIG. 1) and a gate pad 152, a drain bus (not shown) and a drain pad 162, a source bus (not shown) and a source pad 172, and a first field plate FP1. In some embodiments, the material of the first metal layer M1 is metal material having low resistance such as AlCu.

The height H1 between the first field plate FP1 and the semiconductor substrate 110 is greater than the height H1 between the second field plate FP2 and the semiconductor substrate 110, thus a ratio between the gate-source charge (Q_{gs}) and gate-drain charge (Q_{gd}) can be tuned. Additionally, the first field plate FP1, the gate pad 152, the drain pad 162, and the source pad 172 are defined by the same patterning process, thus the mask number and the manufacturing processes can be reduced.

Reference is made to both FIG. 1 and FIG. 5. In some embodiments, the gate plugs 154, the drain plugs 164, and the source plugs 174 are disposed only on the active region A1 and are not disposed on the isolation region A2. In some embodiments, optionally, the first field plate FP1 and the second field plate FP2 are further interconnected by a conductive plug 190 disposed at the isolation region A2.

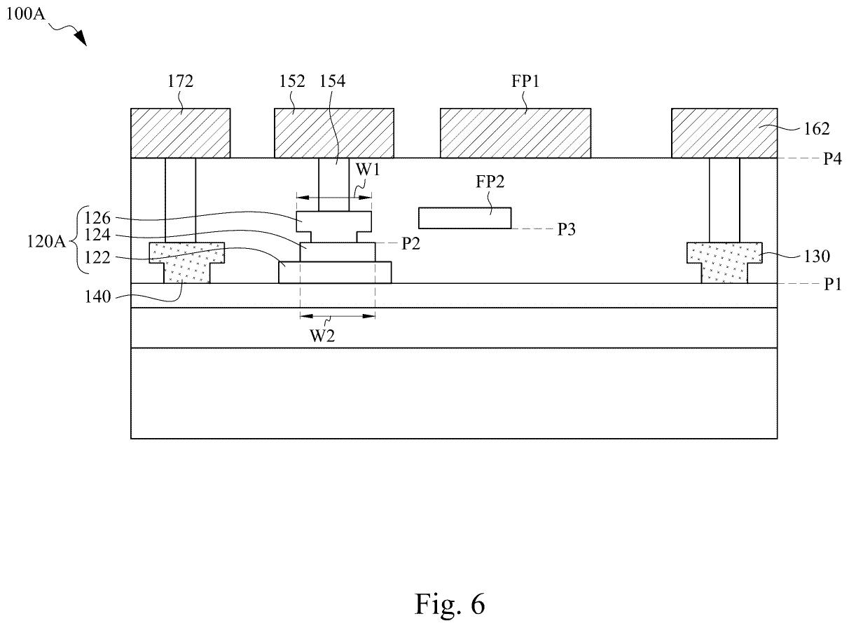

Reference is made to FIG. 6, which is a cross-sectional view of the semiconductor device according to some other embodiments of the disclosure, in which the cross-section can refer to line A-A of FIG. 1. In some embodiments, as shown in the semiconductor device 100A, the gate structure 120A can further include a gate electrode layer 126 disposed on the gate metal layer 124, to further reduce the resistance of the gate structure 120A. The gate electrode layer 126 can be single layer or multiple layers of conductive materials. In some embodiments, the material of the gate electrode layer 126 includes tiN, Ti, AlCu, or combinations thereof.

In some embodiments, the top of the gate electrode layer 126 is wider than the bottom of the gate electrode layer 126 such as the width W1 of the top surface of the gate electrode layer 126 is greater than the width W2 of the gate metal layer 124 thereby increasing a contact area between the gate plugs 154 and the gate structure 120A, to further reduce the contact resistance between the gate plugs 154 and the gate structure 120A.

As shown in the embodiments of the semiconductor device 100A, the plane P2 on where the gate electrode layer 126 is located is higher than the plane P1 on where the drain electrode 130 and the source electrode 140 are located. The plane P3 on where the second field plate FP2 is located is different from the plane P2 on where the gate electrode layer 126 is located. The plane P4 on where the gate pad 152, the drain pad 162, and the source pad 172 are located is higher than the plane P2 on where the gate electrode layer 126 is located.

According to some embodiments of the semiconductor device of the disclosure, the first field plate and the gate pad are defined by the same patterning process thus the mask number and the manufacturing processes can be reduced. The height level of the first field plate is different from the height level of the second field plate such that the electric field of the semiconductor device can be tuned. Additionally, the gate structure and the gate pad are connected by the gate plugs at the active region, the gate resistance can be greatly reduced so that the on-off loss can be reduced and the on-off frequency can be improved when component is switched on or off by the gate.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A semiconductor device comprising:
a semiconductor substrate comprising an active region and an isolation region disposed at a side of the active region;
a gate structure disposed on the active region of the semiconductor substrate;
a source electrode and a drain electrode disposed on the active region of the semiconductor substrate and at opposite sides of the gate structure;
a dielectric layer covering the semiconductor substrate, the gate structure, the source electrode, and the drain electrode;
a gate pad disposed on the dielectric layer, wherein the gate pad overlaps the gate structure in a vertical projection;
a plurality of gate plugs disposed in the dielectric layer and on the active region of the semiconductor substrate, wherein the plurality of gate plugs electrically connect the gate pad to the gate structure; and
a first field plate disposed on the dielectric layer, wherein the first field plate is at the same level as the gate pad and is laterally spaced from the gate pad, wherein a material of the gate pad and a material of the first field plate are the same.

2. The semiconductor device of claim 1, further comprising:
a drain pad disposed on the dielectric layer, wherein the drain pad is at the same level as the gate pad, and the drain pad overlaps the drain electrode in a vertical projection, wherein the first field plate is disposed between the gate pad and the drain pad; and
a plurality of drain plugs disposed in the dielectric layer and on the active region of the semiconductor substrate, wherein the plurality of drain plugs electrically connect the drain pad to the drain electrode.

3. The semiconductor device of claim 1, further comprising:
a source pad disposed on the dielectric layer, wherein the source pad is at the same level as the gate pad, and the source pad overlaps the source electrode in a vertical projection, wherein the gate pad is disposed between the first field plate and the source pad; and
a plurality of source plugs disposed in the dielectric layer and on the active region of the semiconductor substrate, wherein the plurality of source plugs electrically connect the source pad to the source electrode.

4. The semiconductor device of claim 1, further comprising:
a drain pad disposed on the dielectric layer; and
a source pad disposed on the dielectric layer, wherein the first field plate, the drain pad, and the source pad are made of the same material.

5. The semiconductor device of claim 1, further comprising:
a second field plate disposed in the dielectric layer and on the active region of the semiconductor substrate, wherein the second field plate is disposed between the gate structure and the drain electrode, and a height level of the second field plate is between the first field plate and the gate structure.

6. The semiconductor device of claim 1, wherein the gate structure comprises a doping layer, a gate metal layer on the doping layer, and a gate electrode layer on the gate metal layer.

7. The semiconductor device of claim 6, wherein a width of a top surface of the gate electrode layer is greater than a width of the gate metal layer.

8. The semiconductor device of claim 6, wherein a plane on where the gate electrode layer is located is higher than a plane on where the drain electrode and the source electrode are located.

9. The semiconductor device of claim 6, wherein a plane on where the gate pad is located is higher than a plane on where the gate electrode layer is located.

10. The semiconductor device of claim 1, wherein the material of the gate pad and the first field plate comprises AlCu.

11. A method of forming a semiconductor device comprising:
defining an active region and an isolation region at a side of the active region in a semiconductor substrate;
forming a gate structure on the active region of the semiconductor substrate;
forming a drain electrode and a source electrode on the active region of the semiconductor substrate and at opposite sides of the gate structure;
forming a dielectric layer covering the semiconductor substrate, the gate structure, the drain electrode, and the source electrode;
forming a plurality of gate plugs in the dielectric layer, wherein the plurality of gate plugs are connected to the gate structure;
depositing a metal layer on the dielectric layer; and
patterning the metal layer to form a gate pad and a first field plate that are laterally separated from each other, wherein the gate pad is connected to the plurality of gate plugs at the active region.

12. The method of claim 11, wherein a material of the metal layer comprises AlCu.

13. The method of claim 11, further comprising forming a second field plate in the dielectric layer, wherein the second field plate is disposed between the gate structure and the drain electrode, and a height level of the second field plate is between the first field plate and the gate structure.

14. The method of claim 11, wherein the gate structure comprises a doping layer, a gate metal layer on the doping layer, and a gate electrode layer on the gate metal layer.

15. The method of claim 14, wherein a width of a top surface of the gate electrode layer is greater than a width of the gate metal layer.

16. The method of claim 11, wherein patterning the metal layer comprises forming a drain pad on the drain electrode and a source pad on the source electrode, and the gate pad, the drain pad, and the source pad are parallel arranged.

17. The method of claim 11, further comprising forming a plurality of gate plugs at the active region, wherein the gate pad is connected to the gate structure by the plurality of gate plugs.
